(19) United States
(12) Patent Application Publication
(10) Pub. No.: US 2025/0374734 A1
(43) Pub. Date: Dec. 4, 2025

(54) DISPLAY DEVICE, METHOD OF MANUFACTURING DISPLAY DEVICE, AND ELECTRONIC DEVICE COMPRISING DISPLAY DEVICE

(71) Applicant: Samsung Display Co., LTD., Yongin-si (KR)

(72) Inventors: Byoung Yong KIM, Yongin-si (KR); Dong Jun LEE, Yongin-si (KR)

(73) Assignee: Samsung Display Co., LTD., Yongin-si (KR)

(21) Appl. No.: 19/055,792

(22) Filed: Feb. 18, 2025

(30) Foreign Application Priority Data
May 30, 2024 (KR) 10-2024-0070905

(51) Int. Cl. H10H 29/49; H10H 29/01; H10H 29/02

(52) U.S. Cl. CPC H10H 29/49; H10H 29/012; H10H 29/02

(57) ABSTRACT

A display device includes a first pixel and a second pixel disposed on a substrate and having different structures from each other. Each of the first and second pixels includes a light emitting element including a first element electrode and a second element electrode, an anode electrode disposed on the substrate, a cathode electrode disposed on the substrate, a first connection electrode electrically connecting the anode electrode and the light emitting element, and a second connection electrode electrically connecting the cathode electrode and the light emitting element. The second pixel further includes a first connection metal portion that electrically connects the anode electrode and the first element electrode and a second connection metal portion that electrically connects the cathode electrode and the second element electrode.

### CROSS REFERENCE TO RELATED APPLICATION(S)

This application claims priority to and benefits of Korean Patent Application No. 10-2024-0070905 under 35 U.S.C. § 119, filed on May 30, 2024 in the Korean Intellectual Property Office, the entire contents of which are incorporated herein by reference.

### BACKGROUND

### 1. Technical Field

The disclosure relates to a display device and an electronic device including the display device having pixels of reliable operation and excellent display quality and a method of manufacturing the display device, which is capable of decreasing defect and being readily repaired.

### 2. Description of the Related Art

The importance of display devices as communication media, has been emphasized because of the increasing developments of information technology.

The display device includes pixels, and is manufactured through process steps. A portion of manufactured pixels operates abnormally, and the abnormal pixel may be required.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a method of manufacturing a display device, which is capable of decreasing defect and being readily repaired.

Embodiments provide a display device and an electronic device including the display device having pixels of reliable operation and excellent display quality.

However, embodiments of the disclosure are not limited to those set forth herein. The above and other embodiments will become more apparent to one of ordinary skill in the art to which the disclosure pertains by referencing the detailed description of the disclosure given below.

According to an embodiment of the disclosure, a display device may include a first pixel and a second pixel disposed on a substrate and having different structures from each other. Each of the first and second pixels may include a light emitting element including a first element electrode and a second element electrode, an anode electrode disposed on the substrate, a cathode electrode disposed on the substrate, a first connection electrode electrically connecting the anode electrode and the light emitting element, and a second connection electrode electrically connecting the cathode electrode and the light emitting element. The second pixel may further include a first connection metal portion that electrically connects the anode electrode and the first element electrode and a second connection metal portion that electrically connects the cathode electrode and the second element electrode.

According to an embodiment, the first and second connection metal portions may not be included in the first pixel.

According to an embodiment, the first connection metal portion and the second connection metal portion may be spaced apart from each other in a direction in which the anode electrode and the cathode electrode are spaced apart from each other.

According to an embodiment, the anode electrode may include a first anode electrode, a second anode electrode, and a third anode electrode. Each of the first and second pixels may include a first sub-pixel including the first anode electrode, a second sub-pixel including the second anode electrode, and a third sub-pixel including the third anode electrode. The cathode electrode may be a common electrode for the first sub-pixel, the second sub-pixel, and the third sub-pixel. The light emitting element of each of the first and second pixels may include a first light emitting element electrically connected to the first anode electrode, a second light emitting element electrically connected to the second anode electrode, and a third light emitting element electrically connected to the third anode electrode. At least one of the first light emitting element, the second light emitting element, and the third light emitting element of the second pixel may be a repair light emitting element. The repair light emitting element may be electrically connected to the first and second connection metal portions.

According to an embodiment, at least a portion of the first and second connection metal portions may be disposed around the repair light emitting element in a plan view.

According to an embodiment, at least a portion of each of the first connection metal portion and the second connection metal portion may be disposed between the anode electrode and the cathode electrode.

According to an embodiment, at least one of the first and second connection metal portions may cover a side surface of each of the anode electrode and the cathode electrode.

According to an embodiment, the anode electrode and the first connection electrode may have end portions that do not overlap each other in a plan view.

According to an embodiment, each of the first and second connection metal portions may include at least one of silver (Ag), copper (Cu), and gold (Au).

According to an embodiment, the light emitting element may include a repair light emitting element electrically connected to the first and second connection metal portions in the second pixel. In the first pixel, the first element electrode and the second element electrode of the light emitting element may face the substrate. In the second pixel, the first element electrode and the second element electrode of the repair light emitting element may face the substrate.

According to an embodiment, the light emitting element may include a repair light emitting element electrically connected to the first and second connection metal portions in the second pixel. In the first pixel, the first element electrode and the second element electrode of the light emitting element may face an upper portion of the display device. In the second pixel, the first element electrode and the second element electrode of the repair light emitting element may face the substrate.

According to an embodiment, the display device may further include an insulating pattern layer covering a portion of each of the anode electrode and the cathode electrode and forming a base on which the first connection electrode and the second connection electrode are disposed. In the second pixel, a side surface of the insulating pattern layer may be adjacent to at least one of the first and second connection metal portions.

According to an embodiment, in the second pixel, the at least one of the first and second connection metal portions may cover a side surface of each of the insulating pattern layer, the anode electrode, and the first connection electrode.

According to an embodiment, in the second pixel, the insulating pattern layer may have an end portion that does not overlap end portions of the anode electrode and the first connection electrode in a plan view.

According to an embodiment of the disclosure, a method of manufacturing a display device including a non-repair pixel and a repair pixel may include patterning an anode electrode and a cathode electrode in each of the non-repair pixel and the repair pixel on a substrate, disposing a light emitting element including a first element electrode and a second element electrode on the anode electrode and the cathode electrode in each of the non-repair pixel and the repair pixel, patterning a first connection electrode electrically connecting the anode electrode and the first element electrode and a second connection electrode electrically connecting the cathode electrode and the second element electrode in each of the non-repair pixel and the repair pixel, removing the light emitting element in the repair pixel, forming a connection metal portion in the repair pixel by providing a conductive material having a liquid crystal state, and disposing a repair light emitting element on the connection metal portion.

According to an embodiment, the forming of the connection metal portion may include printing a liquid metal. The removing of the light emitting element may include removing the light emitting element using a laser.

According to an embodiment, the method may further include forming a repair opening by removing at least a portion of each of the anode electrode, the cathode electrode, the first connection electrode, and the second connection electrode in the repair pixel.

According to an embodiment, the forming of the connection metal portion may include providing the liquid metal to the repair opening, and disposing the liquid metal on end portions of each of the anode electrode, the cathode electrode, the first connection electrode, and the second connection electrode adjacent to the repair opening.

According to an embodiment, the repair light emitting element in the repair pixel and the light emitting element in the non-repair pixel may be light emitting elements of a flip chip type.

According to an embodiment, the repair light emitting element in the repair pixel may be a light emitting element of a flip chip type. The light emitting element in the non-repair pixel may be a light emitting element of a lateral type.

According to an embodiment of the disclosure, a display device and a method of manufacturing the display device may be capable of decreasing defect and being readily repaired. A risk on a manufacturing process may be reduced and a repair process may be readily performed.

According to an embodiment of the disclosure, a display device and a method of manufacturing the display device may have pixels of reliable operation and excellent display quality.

According to an embodiment of the disclosure, an electronic device may include: a processor that provides input image data; a display device that displays an image based on the input image data, the display device including sub-pixel areas; and a power supply that supplies power to the display device. The display device may include a first pixel and a second pixel disposed on a substrate and having different structures from each other. Each of the first and second pixels may include a light emitting element including a first element electrode and a second element electrode, an anode electrode disposed on the substrate, a cathode electrode disposed on the substrate, a first connection electrode electrically connecting the anode electrode and the light emitting element, and a second connection electrode electrically connecting the cathode electrode and the light emitting element. The second pixel may further include a first connection metal portion that electrically connects the anode electrode and the first element electrode and a second connection metal portion that electrically connects the cathode electrode and the second element electrode.

### BRIEF DESCRIPTION OF THE DRAWINGS

An additional appreciation according to the embodiments of the disclosure will become more apparent by describing in detail the elements thereof with reference to the accompanying drawings, wherein:

FIG. 1 is a schematic plan view illustrating a display device according to an embodiment;

FIG. 2 is a schematic cross-sectional view illustrating a display device according to an embodiment;

FIG. 3 is a schematic cross-sectional view illustrating a display device according to an embodiment;

FIG. 4 is a schematic block diagram illustrating a pixel according to an embodiment;

FIGS. 5 and 6 are schematic plan views each illustrating a pixel according to an embodiment;

FIG. 7 is a schematic cross-sectional view illustrating a light emitting element according to an embodiment;

FIG. 8 is a schematic cross-sectional view illustrating a display device according to an embodiment;

FIG. 9 illustrates a schematic cross-sectional view taken along line B˜B′ of FIG. 5 and a cross-sectional view taken along line C˜C′ of FIG. 6 according to an embodiment;

FIGS. 10 and 11 are schematic enlarged views of an area EA1 of FIG. 9;

FIG. 12 illustrates a schematic cross-sectional view taken along line B˜B′ of FIG. 5 and a cross-sectional view taken along line C˜C′ of FIG. 6 according to an embodiment;

FIGS. 13 to 15 are schematic enlarged views of an area EA2 of FIG. 11;

FIGS. 16 to 21 are schematic cross-sectional views for each process step illustrating a method of manufacturing a display device according to an embodiment;

FIGS. 22 to 25 are schematic cross-sectional views for each process step illustrating a method of manufacturing a display device according to an embodiment;

FIG. 26 is a block diagram illustrating an embodiment of an electronic device; and

FIGS. 27 to 30 are perspective views illustrating application examples of the electronic device of FIG. 26.

### DETAILED DESCRIPTION OF THE EMBODIMENT

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

The disclosure relates to a display device, a method of manufacturing the display device, and an electronic device including the display device. Hereinafter, a display device, a method of manufacturing the display device, and an electronic device including the display device according to an embodiment is described with reference to the accompanying drawings.

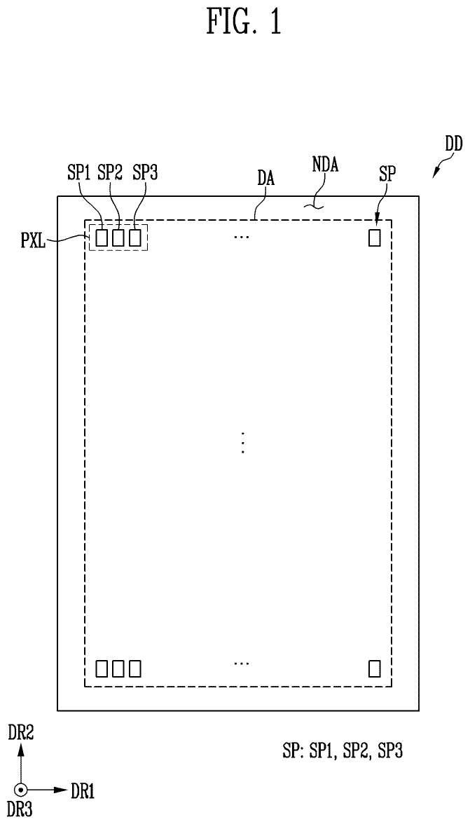

FIG. 1 is a schematic plan view illustrating a display device according to an embodiment.

Referring to FIG. 1, the display device DD may include a display area DA and a non-display area NDA. The display device DD may display an image through the display area DA. The non-display area NDA may be disposed adjacent to (e.g., disposed around or surround) the display area DA.

The display device DD may include the sub-pixels SP in the display area DA. The sub-pixels SP may be disposed (e.g., arranged) along a first direction DR1 and a second direction DR2 intersecting (e.g., crossing) the first direction DR1. For example, the sub-pixels SP may be disposed (e.g., arranged) in a matrix form along the first direction DR1 and the second direction DR2. In other embodiments, the sub-pixels SP may be disposed (e.g., arranged) in a zigzag form along the first direction DR1 and the second direction DR2. An arrangement of the sub-pixels SP may vary according to embodiments. The first direction DR1 may be a row direction, and the second direction DR2 may be a column direction.

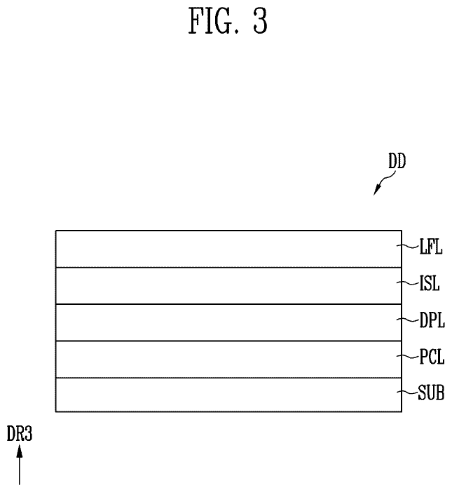

Two or more sub-pixels among the sub-pixels SP may form (or be included in) a pixel PXL. In FIG. 3, the pixel PXL may include three sub-pixels SP1 to SP3 (e.g., a first sub-pixel SP1, a second sub-pixel SP2, and a third sub-pixel SP3), but the disclosure is not limited thereto. For example, the pixel PXL may include two sub-pixels. Hereinafter, for convenience of description, the pixel PXL (or the sub-pixels SP) may include the first to third sub-pixels SP1 to SP3.

Each of the first to third sub-pixels SP1 to SP3 may generate light of one of various colors such as red, green, blue, cyan, magenta, and yellow. Hereinafter, for clear and concise description, the first sub-pixel SP1 may generate light of a red color, the second sub-pixel SP2 may generate light of a green color, and the third sub-pixel SP3 may generate light of a blue color. However, the disclosure is not limited thereto.

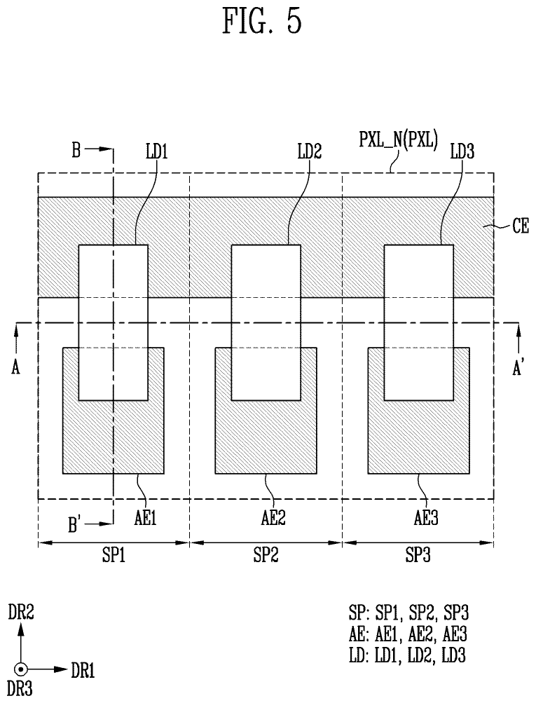

Each of the first to third sub-pixels SP1 to SP3 may include at least one light emitting element LD (e.g., refer to FIG. 5) generating light. In other embodiments, the light emitting elements of the first to third sub-pixels SP1 to SP3 may generate light of a same color. For example, the light emitting elements LD of the first to third sub-pixels SP1 to SP3 may generate the light of the blue color. In other embodiments, the light emitting elements of the first to third sub-pixels SP1 to SP3 may generate light of different colors. For example, the light emitting elements of the first to third sub-pixels SP1 to SP3 may generate light of a red color, a green color, and a blue color, respectively.

The display device DD may include a light emitting diode display panel (LED display panel) using a micro scale or nano scale of light emitting diode as the light emitting element LD, a light emitting display panel, which emit light independently, such as an organic light emitting display panel (OLED panel) using an organic light emitting diode as a light emitting element, or the like. Hereinafter, for convenience of description, the light emitting element LD may be a light emitting diode including an inorganic material.

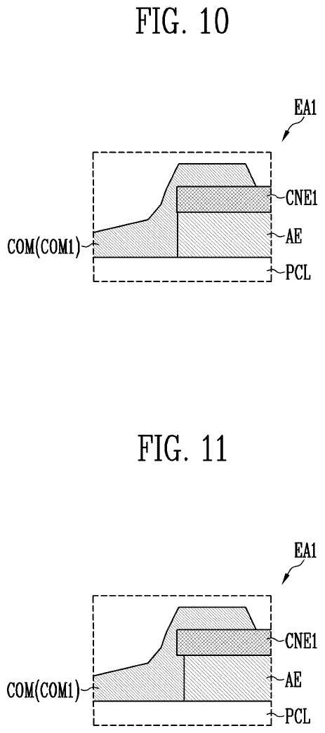

A component for controlling the sub-pixels SP may be disposed in the non-display area NDA. Lines may be electrically connected to the sub-pixels SP, and include a gate line, a data line, a power line, a pixel control line, and the like. The lines may be electrically connected to the pixel circuits PXC (e.g., refer to FIG. 10) for driving the sub-pixels SP and disposed in the non-display area NDA. A gate driver, a data driver, a voltage generator, a controller, and the like may be disposed in the non-display area NDA and operate the sub-pixels SP.

In other embodiments, the display area DA may have various shapes. The display area DA may have a closed loop shape including sides of a straight line and/or a curved line. For example, the display area DA may have shapes of a polygon, a circle, a semicircle, an ellipse, and the like.

In other embodiments, the display device DD may have a flat display surface. In other embodiments, the display device DD may have a display surface that is at least partially round. In other embodiments, the display device DD may be bendable, foldable, or rollable. The display device DD and/or a substrate of the display device DD may include flexible materials.

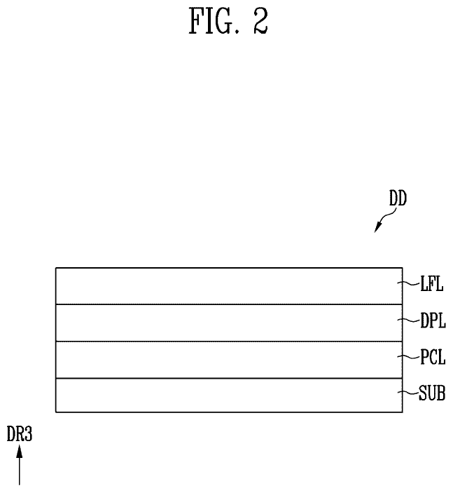

FIG. 2 is a schematic cross-sectional view illustrating a display device according to an embodiment.

Referring to FIG. 2, the display device DD may include a substrate SUB, a pixel circuit layer PCL, a display element layer DPL, and a light functional layer LFL. The substrate SUB, the pixel circuit layer PCL, the display element layer DPL, and the light functional layer LFL may be sequentially stacked on the substrate SUB in a third direction DR3 intersecting (e.g., crossing) the first and second directions DR1 and DR2.

The substrate SUB may be formed of an insulating material such as glass or resin. For example, the substrate SUB may include a glass substrate. In other embodiments, the substrate SUB may include a polyimide (PI) substrate. In other embodiments, the substrate SUB may include a silicon wafer substrate formed using a semiconductor process. In other embodiments, the substrate SUB may be formed of a flexible material that may be bent or folded, and may have a single-layer structure or a multi-layer structure.

The pixel circuit layer PCL may be disposed on the substrate SUB. The pixel circuit layer PCL may include insulating layers, semiconductor patterns, and conductive patterns. The semiconductor patterns and the conductive patterns of the pixel circuit layer PCL may be disposed between the insulating layers. The conductive patterns of the pixel circuit layer PCL may function as (or be implemented with) circuit elements, lines, and the like.

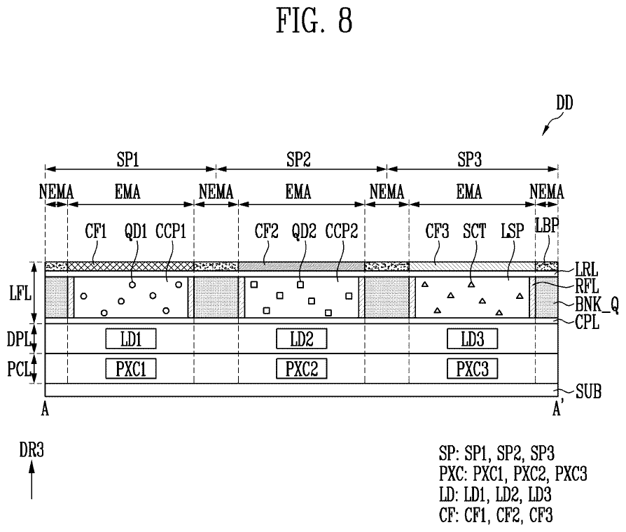

The pixel circuit layer PCL may include a pixel circuit PXC (e.g., refer to FIG. 8). The pixel circuit PXC may be provided with transistors and one or more capacitors.

The lines of the pixel circuit layer PCL may include lines electrically connected to the sub-pixels SP (e.g., refer to FIG. 1). The lines of the pixel circuit layer PCL may include various signal lines and/or voltage lines desirable for driving the display element layer DPL.

The display element layer DPL may be disposed on the pixel circuit layer PCL. The display element layer DPL may include light emitting elements LD (e.g., refer to FIG. 5) of the sub-pixels SP.

The light functional layer LFL may be disposed on the display element layer DPL. The light functional layer LFL may include light conversion pattern layers CCP1 and CCP2 (e.g., refer to FIG. 8) having color conversion particles QD1 and QD2 (e.g., refer to FIG. 8) and/or scattering particles SCT (e.g., refer to FIG. 8). For example, the color conversion particles QD1 and QD2 may include quantum dots. The quantum dots may change a wavelength (or a color) of light emitted from the display element layer DPL. The light functional layer LFL may further include light scattering pattern layers LSP (e.g., refer to FIG. 8) having the scattering particles SCT that scatter provided light. In other embodiments, the light conversion pattern layers CCP1 and CCP2 and the light scattering pattern layers LSP may be omitted.

The light functional layer LFL may further include color filters CF (e.g., refer to FIG. 8). The color filter CF may selectively transmit light of a wavelength (e.g., a specific wavelength, a specific color, or the like). In other embodiments, the color filter CF may be omitted.

A window for protecting an exposure surface (or an upper surface) of the display device DD may be provided on the light functional layer LFL. The window may protect the display device DD from external shock (e.g., impact, scratch, or the like). The window may be coupled to (or combined with) the light functional layer LFL through an optically transparent adhesive (or cohesive) member. The window may have a multi-layer structure selected from a glass substrate, a plastic film, and a plastic substrate. The multi-layer structure may be formed through a continuous process or an adhesion process using an adhesive layer. All or a portion of the window may be flexible.

FIG. 3 is a schematic cross-sectional view illustrating a display device according to an embodiment.

Referring to FIG. 3, the display device DD may include the substrate SUB, the pixel circuit layer PCL, the display element layer DPL, an input sensing layer ISL, and the light functional layer LFL. The substrate SUB, the pixel circuit layer PCL, the display element layer DPL, and the light functional layer LFL may be configured similarly to the substrate SUB, the pixel circuit layer PCL, the display element layer DPL, and the light functional layer LFL described with reference to FIG. 2. Hereinafter, detailed description of the same or similar constituent elements (e.g., the substrate SUB, the pixel circuit layer PCL, the display element layer DPL, and the light functional layer LFL) is omitted.

The input sensing layer ISL may sense a user input on an upper surface (or a display surface) of the display device DD. The input sensing layer ISL may include components suitable for sensing an external object such as a user's hand, or a pen. For example, the input sensing layer ISL may include touch electrodes.

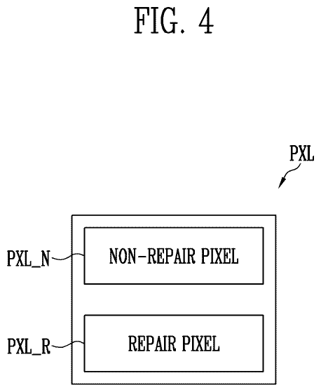

With reference to FIGS. 4 to 15, a display device including a repair pixel PXL_R is described. Detailed description of the same or similar constituent elements is omitted and not repeated.

FIG. 4 is a schematic block diagram illustrating a pixel according to an embodiment.

Referring to FIG. 4, the pixel PXL may include pixels PXL having different structures. The pixels PXL may include a non-repair pixel (or normal pixel) PXL_N (for example, a first pixel) and a repair pixel (or abnormal pixel) PXL_R (for example, a second pixel).

The non-repair pixel PXL_N and the repair pixel PXL_R may have different structures.

The non-repair pixel PXL_N may be a pixel PXL inspected as a pixel that operates normally and thus a repair process is not performed after the light emitting element LD is disposed (for example, transferred) on the substrate SUB during a manufacturing process of the display device DD. For example, in case that the pixel PXL operates normally, the repair process may not be performed on the non-repair pixel PXL_N during the manufacturing process of the display device DD.

The repair pixel PXL_R may be a pixel PXL inspected as a pixel that does not operate normally and thus the repair process is performed after the light emitting element LD is disposed (for example, transferred) on the substrate SUB during the manufacturing process of the display device DD. For example, in case that the pixel PXL does not operate normally, the repair process may be performed on the repair pixel PXL_R during the manufacturing process of the display device DD.

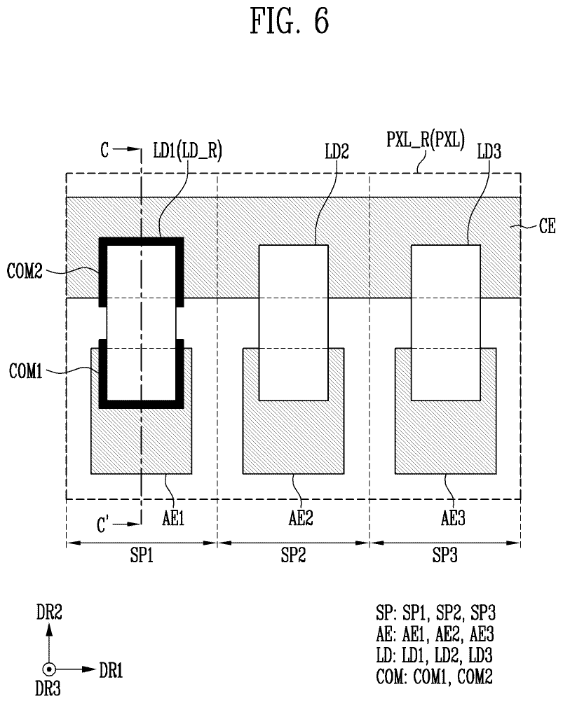

Accordingly, the repair pixel PXL_R may further include a connection metal portion COM (e.g., refer to FIG. 6), which is not included in the non-repair pixel PXL_N and disposed (for example, selectively disposed) in the repair pixel PXL_R for the repair process. The repair process may be performed based on the connection metal portion COM, and reliability of the repair process may be improved.

With reference to FIGS. 5 to 8, a display device DD including a non-repair pixel PXL_N and a repair pixel PXL_R according to an embodiment is described.

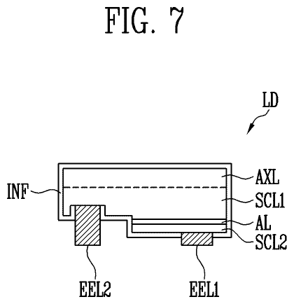

FIGS. 5 and 6 are schematic plan views each illustrating a pixel according to an embodiment. FIG. 5 may illustrate a non-repair pixel PXL_N according to an embodiment. FIG. 6 may illustrate a repair pixel PXL_R according to an embodiment. FIG. 7 is a schematic cross-sectional view illustrating a light emitting element according to an embodiment. FIG. 8 is a schematic cross-sectional view illustrating a display device according to an embodiment. FIG. 8 is a schematic cross-sectional view taken along line A˜A′ of FIGS. 5 and 6.

Referring to FIGS. 5 to 8, the pixel PXL may include the first to third sub-pixels SP1 to SP3. The first to third sub-pixels SP1 to SP3 may be disposed (e.g., arranged) in the first direction DR1. However, an arrangement of the pixel PXL is not limited thereto and may be variously changed according to an embodiments.

The pixel PXL (for example, each of the non-repair pixel PXL_N and the repair pixel PXL_R) may include an anode electrode AE.

The anode electrode AE may include a first anode electrode AE1 disposed in the first sub-pixel SP1, a second anode electrode AE2 disposed in the second sub-pixel SP2, and a third anode electrode AE3 disposed in the third sub-pixel SP3.

The first anode electrode AE1 may be electrically connected to a first pixel circuit PXC1, which is the pixel circuit PXC of the first sub-pixel SP1. The second anode electrode AE2 may be electrically connected to a second pixel circuit PXC2, which is the pixel circuit PXC of the second sub-pixel SP2. The third anode electrode AE3 may be electrically connected to a third pixel circuit PXC3, which is the pixel circuit PXC of the third sub-pixel SP3.

According to an embodiment, the first to third anode electrodes AE1 to AE3 may be disposed along the first direction DR1 and may be spaced apart from each other along the first direction DR1.

The pixel PXL (for example, each of the non-repair pixel PXL_N and the repair pixel PXL_R) may include a cathode electrode CE.

The cathode electrode CE may be a common electrode for the sub-pixels SP (e.g., the first to third sub-pixels SP1, SP2, and SP3). Although not shown in the drawing, the cathode electrode CE may be a common electrode for the pixel PXL and other adjacent pixels PXL.

According to an embodiment, the cathode electrode CE may extend in the first direction DR1. Although not shown, according to an embodiment, a portion of the cathode electrode CE may extend in the first direction DR1, and another portion of the cathode electrode CE may extend in the second direction DR2. Thus, the cathode electrode CE may be used as the common electrode for the sub-pixels SP (e.g., the entire sub-pixels SP). As described above, the cathode electrode CE may have various shapes.

The cathode electrode CE and the anode electrode AE may be disposed at a same height. For example, the cathode electrode CE and the first to third anode electrodes AE1 to AE3 may be patterned in a same process. The cathode electrode CE and the first to third anode electrodes AE1 to AE3 may include a same conductive material.

The cathode electrode CE may be spaced apart from the first to third anode electrodes AE1 to AE3 (for example, spaced apart in the second direction DR2).

The pixel PXL (for example, each of the non-repair pixel PXL_N and the repair pixel PXL_R) may include the light emitting element LD.

The light emitting element LD may include a first semiconductor layer SCL1, an active layer AL, and a second semiconductor layer SCL2. The light emitting element LD may further include an auxiliary layer AXL and an element insulating layer INF. The light emitting element LD may further include a first element electrode EEL1 and a second element electrode EEL2.

The light emitting element LD may include a light emitting stack in which the auxiliary layer AXL, the first semiconductor layer SCL1, the active layer AL, and the second semiconductor layer SCL2 are sequentially stacked each other.

The first semiconductor layer SCL1 may provide electrons to the active layer AL. For example, the first semiconductor layer SCL1 may include at least one n-type semiconductor layer as an example. For example, the first semiconductor layer SCL1 may include at least one semiconductor material among gallium nitride (GaN), aluminum gallium nitride (AlGaN), indium gallium nitride (InGaN), aluminum nitride (AlN), and indium nitride (InN), and may be an n-type semiconductor layer doped with a first conductive dopant (or an n-type dopant) including at least one of silicon (Si), germanium (Ge), and tin (Sn). However, a material of the first semiconductor layer SCL1 is not limited thereto, and various other materials may form (or be included in) the first semiconductor layer SCL1. In an embodiment, the first semiconductor layer SCL1 may include a gallium nitride (GaN) semiconductor material doped with the first conductive dopant (or the n-type dopant).

The auxiliary layer AXL may include a semiconductor material that is not doped with an impurity. For example, the auxiliary layer AXL and the first semiconductor layer SCL1 may include a same semiconductor material, and the auxiliary layer AXL may not include the first conductive dopant.

According to an embodiment, the first semiconductor layer SCL1 and the auxiliary layer AXL may form (or be included in) an n-type semiconductor layer.

The active layer AL may be disposed between the first semiconductor layer SCL1 and the second semiconductor layer SCL2 and may be an area where electrons and holes are recombined. The electrons and the holes may recombine in the active layer AL, and energy level may be transited to a low level. Thus, light having a wavelength corresponding to the transition of the energy level may be generated. The active layer AL may be formed as a single or multiple quantum well structure. In case that the active layer AL is formed as a multiple quantum well structure, layers (e.g., triple layers) including a barrier layer, a strain reinforcing layer, and a well layer may be repeatedly stacked each other and form the active layer AL. However, embodiments of the active layer AL are not limited thereto.

The second semiconductor layer SCL2 may be disposed on the active layer AL and provide holes to the active layer AL. The second semiconductor layer SCL2 may include a semiconductor layer of a type different from that of the first semiconductor layer SCL1. As an example, the second semiconductor layer SCL2 may include at least one p-type semiconductor layer. For example, the second semiconductor layer SCL2 may include at least one semiconductor material among gallium nitride (GaN), aluminum gallium nitride (AlGaN), indium gallium nitride (InGaN), aluminum nitride (AlN), and indium nitride (InN), and may be a p-type semiconductor layer doped with a second conductive dopant (or a p-type dopant) including at least one of magnesium (Mg), zinc (Zn), calcium (Ca), strontium (Sr), and barium (Ba). However, a material of the second semiconductor layer SCL2 is not limited thereto, and various other materials may form (or be included in) the second semiconductor layer SCL2. In an embodiment, the second semiconductor layer SCL2 may include a gallium nitride (GaN) semiconductor material doped with the second conductive dopant (or the p-type dopant).

The first and second element electrodes EEL1 and EEL2 may face a same direction (for example, a direction opposite to the third direction DR3). The first element electrode EEL1 may be disposed on the second semiconductor layer SCL2 exposed by the element insulating layer INF and may be electrically connected to the second semiconductor layer SCL2. The second element electrode EEL2 may be disposed on the first semiconductor layer SCL1 exposed by the element insulating layer INF and may be electrically connected to the first semiconductor layer SCL1. For example, the element insulating layer INF may include an opening through which the second semiconductor layer SCL2 is electrically connected to the first element electrode EEL1 and another opening through which the first semiconductor layer SCL1 is electrically connected to the second element electrode EEL2. The first and second element electrodes EEL1 and EEL2 may include eutectic metal.

The element insulating layer INF may cover an outer surface of the light emitting stack (e.g., the auxiliary layer AXL, the first semiconductor layer SCL1, the active layer AL, and the second semiconductor layer SCL2). The element insulating layer INF may prevent an electrical short circuit that may occur in case that the active layer AL comes into contact with a conductive material other than the first and second semiconductor layers SCL1 and SCL2. For example, the active layer AL may be electrically connected to the first and second semiconductor layers SCL1 and SCL2, and the element insulating layer INF may electrically insulate the active layer AL from other elements. The element insulating layer INF may include a transparent insulating material. The element insulating layer INF may expose lower surfaces of the first and second element electrodes EEL1 and EEL2 through the openings.

The light emitting element LD may be disposed on the anode electrode AE and the cathode electrode CE. The light emitting element LD may include a first light emitting element LD1 included in the first sub-pixel SP1, a second light emitting element LD2 included in the second sub-pixel SP2, and a third light emitting element LD3 included in the third sub-pixel SP3.

According to an embodiment, the first to third light emitting elements LD1 to LD3 may be spaced apart from each other along the first direction DR1 and may be disposed along the first direction DR1.

The first light emitting element LD1 may be disposed on the first anode electrode AE1 and a first portion of the cathode electrode CE. The second light emitting element LD2 may be disposed on the second anode electrode AE2 and a second portion of the cathode electrode CE. The third light emitting element LD3 may be disposed on the third anode electrode AE3 and a third portion of the cathode electrode CE.

According to an embodiment, the non-repair pixel PXL_N and the repair pixel PXL_R may have different structures. For example, the non-repair pixel PXL_N may not include a connection metal portion COM, and the repair pixel PXL_R may further include the connection metal portion COM. Thus, the non-repair pixel PXL_N and the repair pixel PXL_R may have different structures.

The connection metal portion COM may be disposed adjacent to at least a portion of the light emitting elements LD included in the repair pixel PXL_R. The connection metal portion COM may not be included in the non-repair pixel PXL_N.

According to an embodiment, a light emitting element LD to which the connection metal portion COM is adjacent may be a repair light emitting element LD_R. According to an embodiment, the repair light emitting element LD_R may be one or more of the first to third light emitting elements LD1 to LD3.

For example, the first light emitting element LD1 may be the repair light emitting element LD_R, and the second and third light emitting elements LD2 and LD3 may not be the repair light emitting element LD_R. However, the disclosure is not limited thereto. For example, the repair light emitting element LD_R may be one selected from the first to third light emitting elements LD1 to LD3. For example, the repair light emitting elements LD_R may be two selected from the first to third light emitting elements LD1 to LD3. For example, each of the first to third light emitting elements LD1 to LD3 may be the repair light emitting element LD_R.

Hereinafter, for convenience of description, the first light emitting element LD1 may be the repair light emitting element LD_R.

The connection metal portion COM may be patterned during a repair process in the manufacturing process of the display device DD. The connection metal portion COM may be disposed under the repair light emitting element LD_R disposed (for example, transferred) during the repair process of the display device DD. For example, the connection metal portion COM may be formed during the repair process of the display device DD and disposed between the repair light emitting element LD_R and the pixel circuit layer PCL.

In a plan view, the connection metal portion COM may overlap the anode electrode AE (e.g., a portion of the anode electrode AE) in a plan view, may overlap the cathode electrode CE (e.g., a portion of the cathode electrode CE) in a plan view, and may overlap the repair light emitting element LD_R (e.g., a portion of the repair light emitting element LD_R) in a plan view.

A plane may be defined in a direction extending in the first direction DR1 and the second direction DR2, and the substrate SUB may be disposed on the defined plane. According to an embodiment, the third direction DR3 may be a thickness direction of the substrate SUB, and the third direction DR3 may be a light emission direction of the display device DD. For example, the third direction DR3 may be perpendicular to the plane defined by the first and second directions DR1 and DR2.

At least a portion of the connection metal portion COM may be adjacent to (e.g., surround) the repair light emitting element LD_R in a plan view. For example, a portion of the connection metal portion COM may be disposed around the repair light emitting element LD_R in a plan view.

At least a portion of the connection metal portion COM may not overlap the anode electrode AE in a plan view. At least a portion of the connection metal portion COM may not overlap the cathode electrode CE in a plan view. For example, at least a portion of the connection metal portion COM may be disposed between the cathode electrode CE and the anode electrode AE in a plan view.

The connection metal portion COM may include a conductive material that may be melted. For example, the connection metal portion COM may include one or more of silver (Ag), copper (Cu), and gold (Au). For example, the connection metal portion COM may include an alloy of the above-described metals. However, the disclosure is not limited thereto.

The connection metal portion COM may include a first connection metal portion COM1 adjacent to the anode electrode AE and a second connection metal portion COM2 adjacent to the cathode electrode CE.

The first connection metal portion COM1 and the second connection metal portion COM2 may be spaced (e.g., physically spaced) apart from each other. The first connection metal portion COM1 and the second connection metal portion COM2 may be spaced apart from each other in a direction in which the anode electrode AE and the cathode electrode CE are spaced apart from each other (for example, the second direction DR2).

The first connection metal portion COM1 and the second connection metal portion COM2 may be patterned in a same process (for example, formed based on a printing process) and may include a same conductive material.

The connection metal portion COM may have electrical conductivity. For example, the first connection metal portion COM1 may electrically connect the anode electrode AE and the repair light emitting element LD_R. The second connection metal portion COM2 may electrically connect the cathode electrode CE and the repair light emitting element LD_R.

Referring to FIG. 8, a cross-sectional structure of the pixel PXL (for example, the non-repair pixel PXL_N or the repair pixel PXL_R) including the first to third sub-pixels SP1 to SP3 is disclosed.

The display device DD including the pixel PXL according to an embodiment may include the pixel circuit layer PCL disposed on the substrate SUB and including the pixel circuit PXC.

The pixel circuit PXC may include the first pixel circuit PXC1 driving the first sub-pixel SP1 (or the first light emitting element LD1) and electrically connected to the first light emitting element LD1 (or the first anode electrode AE1), the second pixel circuit PXC2 driving the second sub-pixel SP2 (or the second light emitting element LD2) and electrically connected to the second light emitting element LD2 (or the second anode electrode AE2), and the third pixel circuit PXC3 driving the third sub-pixel SP3 (or the third light emitting element LD3) and electrically connected to the third light emitting element LD3 (or the third anode electrode AE3).

The display element layer DPL may include the first to third light emitting elements LD1 to LD3 electrically connected to the first to third pixel circuits PXC1 to PXC3, respectively. According to an embodiment, the first to third light emitting elements LD1 to LD3 may be disposed in an emission area EMA of each of the first to third sub-pixels SP1 to SP3.

The light functional layer LFL may be disposed on the display element layer DPL.

The light functional layer LFL may include a capping layer CPL, an upper bank BNK_Q, a reflective layer RFL, light conversion pattern layers CCP1 and CCP2, the light scattering pattern layer LSP, an optical layer LRL, the color filter CF, and a light blocking pattern layer LBP.

The capping layer CPL may be disposed on the display element layer DPL. The capping layer CPL may protect components (e.g., the light emitting element LD) disposed under the capping layer CPL from external moisture, humidity, and the like. According to an embodiment, the capping layer CPL may include an inorganic material.

The upper bank BNK_Q may be disposed on the capping layer CPL. The upper bank BNK_Q may be disposed in a non-emission area NEMA. The upper bank BNK_Q may form an opening where the light conversion pattern layers CCP1 and CCP2 and the light scattering pattern layer LSP are disposed. The upper bank BNK_Q may include a light blocking material and prevent light mixing between adjacent ones of the sub-pixels SP. In other embodiments, the upper bank BNK_Q may include an organic material. However, the disclosure is not limited thereto.

The reflective layer RFL may be disposed on a side surface of the upper bank BNK_Q. The reflective layer RFL may reflect incident light, and light emission efficiency may be improved. The reflective layer RFL may include a light reflective material. However, the disclosure is not limited thereto.

Each of the first and second light conversion pattern layers CCP1 and CCP2 may be disposed in the opening formed by the upper bank BNK_Q and may be disposed in the emission area EMA (e.g., the emission area EMA of each of the first and second sub-pixels SP1 and SP2). The first and second light conversion pattern layers CCP1 and CCP2 may include the first and second color conversion particles QD1 and QD2, respectively. The first and second light conversion pattern layers CCP1 and CCP2 may include an organic matrix (or an organic material) in which the first and second color conversion particles QD1 and QD2 may be dispersed. According to an embodiment, the first and second light conversion pattern layers CCP1 and CCP2 may further include scattering particles.

The light scattering pattern layer LSP may be disposed in the opening formed by the upper bank BNK_Q and may be disposed in the emission area EMA (e.g., the emission area EMA of the third sub-pixel SP3). The light scattering pattern layer LSP may include scattering particles SCT. The light scattering pattern layer LSP may include an organic matrix (or an organic material) in which the scattering particles SCT may be dispersed.

The optical layer LRL may be disposed on the upper bank BNK_Q, the reflective layer RFL, the first and second light conversion pattern layers CCP1 and CCP2, and the light scattering pattern layer LSP.

The optical layer LRL may be a low refractive layer. According to an embodiment, the optical layer LRL may have a refractive index lower than that of the first and second light conversion pattern layers CCP1 and CCP2. Accordingly, the optical layer LRL may refract or totally reflect light (or corresponding light) according to an incidence angle of light. For example, in case that the incident angle of the light is greater than an angle (e.g., a predetermined or selectable angle), the optical layer LRL may totally reflect the incident light. The optical layer LRL may provide light passing through the first and second light conversion pattern layers CCP1 and CCP2 back to the first and second light conversion pattern layers CCP1 and CCP2. For example, a portion of light from the first and second light conversion pattern layers CCP1 and CCP2 may be reflected (or recycled) at an interface between the optical layer LRL and the first light conversion pattern layer CCP1 (or the second light conversion pattern layer CCP2) toward the first and second light conversion pattern layers CCP1 and CCP2. Accordingly, light conversion efficiency of the first and second light conversion pattern layers CCP1 and CCP2 may be improved.

The color filters CF may be disposed on the optical layer LRL. Each of the color filters CF may be disposed in the emission area EMA. The color filters CF may include a first color filter CF1 included in the first sub-pixel SP1, a second color filter CF2 included in the second sub-pixel SP2, and a third color filter CF3 included in the third sub-pixel SP3.

The color filters CF may include a dye or a pigment that selectively transmits light of a color. For example, the first color filter CF1 may selectively transmit light of a first color, the second color filter CF2 may selectively transmit light of a second color, and the third color filter CF3 may selectively transmit light of a third color.

The light blocking pattern layer LBP may be disposed in the non-emission area NEA and may reduce a risk of color mixing between the sub-pixels SP. The light blocking pattern layer LBP may include various light blocking materials (for example, a black matrix, a carbon black, and the like). In other embodiment, the light blocking pattern layer LBP may be formed by overlapping the first to third color filters CF1 to CF3 along the third direction DR3.

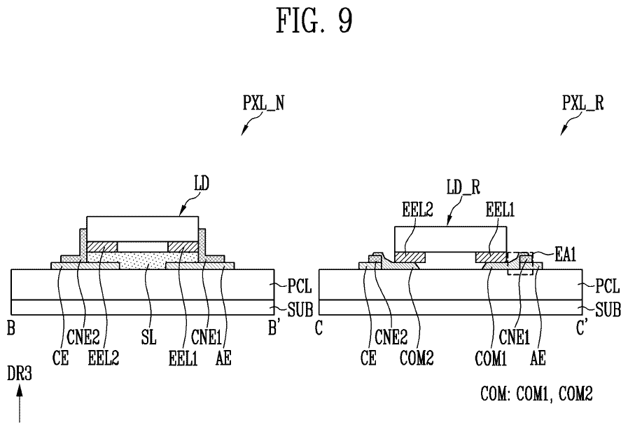

Further referring to FIGS. 9 to 11, a display device DD according to an embodiment is described. Detailed description of the same or similar constituent element is omitted and not repeated.

FIG. 9 illustrates a schematic cross-sectional view taken along line B˜B′ of FIG. 5 and a cross-sectional view taken along line C˜C′ of FIG. 6 according to an embodiment. FIGS. 10 and 11 are schematic enlarged views of an area EA1 of FIG. 9.

Referring to FIGS. 9 and 10, according to an embodiment, the light emitting elements LD of the non-repair pixel PXL_N and the repair light emitting elements LD_R of the repair pixel PXL_R may include a light emitting diode of a same type.

For example, the light emitting elements LD of the non-repair pixel PXL_N may be light emitting elements of a flip chip type. The repair light emitting element LD_R of the repair pixel PXL_R may be a light emitting element of a flip chip type.

In each of the non-repair pixel PXL_N and the repair pixel PXL_R, the anode electrode AE and the cathode electrode CE may be disposed on the pixel circuit layer PCL. The non-repair pixel PXL_N may further include a lower layer SL.

The lower layer SL may be disposed under the light emitting element LD. For example, the lower layer SL may be disposed between the light emitting element LD and the pixel circuit layer PCL. The lower layer SL may cover a portion of each of the anode electrode AE and the cathode electrode CE.

The lower layer SL may be a bonding layer. For example, the lower layer SL may be combined with the first and second element electrodes EEL1 and EEL2 of the light emitting element LD, and may allow the light emitting element LD to be stably disposed. The lower layer SL may include various insulating materials.

In the repair pixel PXL_R, the connection metal portion COM may be disposed between the anode electrode AE and the cathode electrode CE. The connection metal portion COM may be disposed between a first connection electrode CNE1 and a second connection electrode CNE2.

The connection metal portion COM may be disposed under the repair light emitting element LD_R. The repair light emitting element LD_R may be a light emitting element of a flip chip type, and an upper surface of the connection metal portion COM may be electrically connected to the first and second element electrodes EEL1 and EEL2. According to an embodiment, the upper surface of the connection metal portion COM may be electrically connected to each of the first and second element electrodes EEL1 and EEL2.

According to an embodiment, the connection metal portion COM may be combined with the first and second element electrodes EEL1 and EEL2, and may allow the light emitting element LD to be stably disposed.

The connection metal portion COM may have an uneven outer surface (for example, the upper surface). For example, a liquid metal may be printed (e.g., printed on the pixel circuit layer PCL) during a repair process in the manufacturing process of the display device DD, and the connection metal portion COM may be formed in the repair pixel PXL_R. Accordingly, the upper surface of the connection metal portion COM may be relatively uneven.

The liquid metal may be hardened based on a printing process, and the connection metal portion COM may be formed in the repair pixel PXL_R.

The first connection metal portion COM1 may be electrically connected to side surfaces of the anode electrode AE and the first connection electrode CNE1. According to an embodiment, the first connection metal portion COM1 may contact the side surfaces of the anode electrode AE and the first connection electrode CNE1. For example, the first connection metal portion COM1 may be electrically connected to the anode electrode AE and the first connection electrode CNE1 through the side surfaces of the anode electrode AE and the first connection electrode CNE1.

According to other embodiments, the first connection metal portion COM1 may not form an electrical contact surface with the anode electrode AE on an upper surface of the anode electrode AE.

The first connection metal portion COM1 may have a greater thickness as the first connection metal portion COM1 is adjacent to the anode electrode AE and the first connection electrode CNE1. For example, in case that a distance from the anode electrode AE (or a distance from the first connection electrode CNE1) is decreased, the thickness of the first connection metal portion COM1 may be increased. Accordingly, the first connection metal portion COM1 may be stably electrically connected in a side portion formed by the anode electrode AE and the first connection electrode CNE1.

According to an embodiment, the first connection metal portion COM1 may cover the side surfaces of the anode electrode AE and the first connection electrode CNE1. According to an embodiment, since the first connection metal portion COM1 has a melted state during the manufacturing process, even though the side surfaces of the anode electrode AE and the first connection electrode CNE1 are uneven, the first connection metal portion COM1 may stably form an electrical connection path with the anode electrode AE and the first connection electrode CNE1. For example, even though the side surfaces of the anode electrode AE and the first connection electrode CNE1 form the uneven side surfaces (e.g., a step), the first connection metal portion COM1 may be melted during the manufacturing process, and the first connection metal portion COM1 may form the stable electrical connection with the anode electrode AE and the first connection electrode CNE1 by the molten part of the first connection metal portion COM1.

According to an embodiment, the first connection metal portion COM1 may cover an upper surface of the first connection electrode CNE1. Accordingly, the first connection metal portion COM1 may receive an anode voltage through the upper surface of the first connection electrode CNE1.

The second connection metal portion COM2 may be electrically connected to side surfaces of the cathode electrode CE and the second connection electrode CNE2. According to an embodiment, the second connection metal portion COM2 may contact the side surfaces of the cathode electrode CE and the second connection electrode CNE2. For example, the second connection metal portion COM2 may be electrically connected to the cathode electrode CE and the second connection electrode CNE2 through the side surfaces of the cathode electrode CE and the second connection electrode CNE2.

According to other embodiments, the second connection metal portion COM2 may not form an electrical contact surface with the cathode electrode CE in an upper surface of the cathode electrode CE.

The second connection metal portion COM2 may have a greater thickness as the second connection metal portion COM2 is adjacent to the cathode electrode CE and the second connection electrode CNE2. For example, in case that a distance from the cathode CE (or a distance from the second connection electrode CNE2) is decreased, the thickness of the second connection metal portion COM2 may be increased. Accordingly, the second connection metal portion COM2 may be stably electrically connected in a side portion formed by the cathode electrode CE and the second connection electrode CNE2.

According to an embodiment, the second connection metal portion COM2 may cover the side surfaces of the cathode electrode CE and the second connection electrode CNE2. According to an embodiment, since the second connection metal portion COM2 has a melted state during the manufacturing process, even though the side surfaces of the cathode electrode CE and the second connection electrode CNE2 are uneven, the second connection metal portion COM2 may stably form an electrical connection path with the cathode electrode CE and the second connection electrode CNE2. For example, even though the side surfaces of the cathode electrode CE and the second connection electrode CNE2 form the uneven side surfaces (e.g., a step), the second connection metal portion COM2 may be melted during the manufacturing process, and the second connection metal portion COM2 may form the stable electrical connection with the cathode electrode CE and the second connection electrode CNE2 by the molten part of the second connection metal portion COM2.

According to an embodiment, the second connection metal portion COM2 may cover an upper surface of the second connection electrode CNE2. Accordingly, the second connection metal portion COM2 may receive a cathode voltage through the upper surface of the second connection electrode CNE2.

According to an embodiment, the side surfaces of the cathode electrode CE, the anode electrode AE, the first connection electrode CNE1, and the second connection electrode CNE2 facing the repair light emitting element LD_R may be formed through a repair process. For example, a laser may be applied (e.g., irradiated) during the repair process, at least a portion of the cathode electrode CE, the anode electrode AE, the first connection electrode CNE1, and the second connection electrode CNE2 may be removed. Accordingly, a path of an electrical signal supplied for the light emitting element LD to emit light may be damaged. According to an embodiment, a liquid metal may be printed (e.g., printed on an upper surface of the pixel circuit layer PCL and the side surfaces of the cathode electrode CE, the anode electrode AE, the first connection electrode CNE1, and the second connection electrode CNE2) and the connection metal portion COM may be patterned. Thus, an electrical connection structure may be stably formed during the repair process. Since the connection metal portion COM is provided in a liquid form (or a liquid state) on the substrate SUB, an electrical path may be stably formed (or thoroughly defined) without disconnection. Accordingly, even though the repair process is performed, a risk that the disposed repair light emitting element LD_R abnormally operates may be reduced, reliability of the repair process may be improved. Thus, defect of the display device DD may be decreased, and the display device DD may be readily repaired. Accordingly, operation reliability of the pixels PXL may be improved, and the display device DD may have excellent display quality.

According to an embodiment, the first and second connection electrodes CNE1 and CNE2 may be disposed on the anode electrode AE and the cathode electrode CE in the non-repair pixel PXL_N and the repair pixel PXL_R.

According to an embodiment, the first connection electrode CNE1 may be electrically connected to the anode electrode AE and the first element electrode EEL1 of the light emitting element LD (or the repair light emitting element LD_R). For example, in the non-repair pixel PXL_N, a portion of the first connection electrode CNE1 may be disposed on the anode electrode AE, and another portion of the first connection electrode CNE1 may be disposed on a side surface of the first element electrode EEL1. In the repair pixel PXL_R, a portion of the first connection electrode CNE1 may be disposed on the anode electrode AE, and the first connection electrode CNE1 may be electrically connected to the first connection metal portion COM1. For example, the first connection electrode CNE1 of the repair pixel PXL_R may be electrically connected to the first element electrode EEL1 through the first connection metal portion COM1.

According to an embodiment, the second connection electrode CNE2 may be electrically connected to the cathode electrode CE and the second element electrode EEL2 of the light emitting element LD (or the repair light emitting element LD_R). For example, in the non-repair pixel PXL_N, a portion of the second connection electrode CNE2 may be disposed on the cathode electrode CE, and another portion of the second connection electrode CNE2 may be disposed on a side surface of the second element electrode EEL2. In the repair pixel PXL_R, a portion of the second connection electrode CNE2 may be disposed on the cathode electrode CE, and the second connection electrode CNE2 may be electrically connected to the second connection metal portion COM2. For example, the second connection electrode CNE2 of the repair pixel PXL_R may be electrically connected to the second element electrode EEL2 through the second connection metal portion COM2.

According to an embodiment, the anode electrode AE and the first connection electrode CNE1 may overlap each other in a plan view. The cathode electrode CE and the second connection electrode CNE2 may overlap each other in a plan view.

For example (e.g., refer to FIG. 10), the anode electrode AE and the first connection electrode CNE1 may have ends (or end portions) that substantially (or generally) overlap each other in a plan view. The cathode electrode CE and the second connection electrode CNE2 may have ends (or end portions) that substantially (or generally) overlap each other in a plan view.

In other embodiments (e.g., refer to FIG. 11), the anode electrode AE and the first connection electrode CNE1 may have ends (or end portions) that do not overlap each other in a plan view. Side surfaces formed by the anode electrode AE and the first connection electrode CNE1 may form a step each other. The cathode electrode CE and the second connection electrode CNE2 may have ends (or end portions) that do not overlap each other in a plan view. Side surfaces formed by the cathode electrode CE and the second connection electrode CNE2 may form a step each other. According to an embodiment, the first and second connection electrodes CNE1 and CNE2 may protrude with respect to the anode electrode AE and the cathode electrode CE. However, the disclosure is not limited thereto. The anode electrode AE and the cathode electrode CE may protrude with respect to the first and second connection electrodes CNE1 and CNE2.

According to an embodiment, as described above, since the connection metal portion COM provided in the liquid form during the repair process covers the side surfaces of the anode electrode AE and the first connection electrode CNE1 and the side surfaces of the cathode electrode CE and the second connection electrode CNE2, an electrical connection structure may be stably formed in the repair pixel PXL_R.

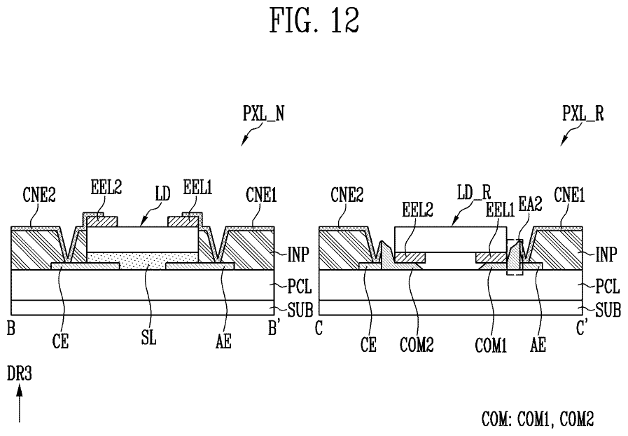

Further referring to FIGS. 12 to 15, a display device DD according to an embodiment is described. Detailed description of the same or similar constituent element is omitted and not repeated.

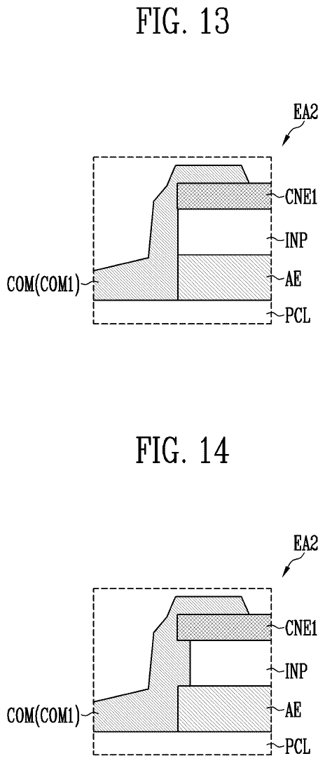

FIG. 12 illustrates a schematic cross-sectional view taken along line B˜B′ of FIG. 5 and a cross-sectional view taken along line C˜C′ of FIG. 6 according to an embodiment. FIGS. 13 to 15 are schematic enlarged views of an area EA2 of FIG. 11.

Referring to FIGS. 12 to 15, the non-repair pixel PXL_N and the repair pixel PXL_R according to the embodiment is different from the non-repair pixel PXL_N and the repair pixel PXL_R of FIGS. 9 to 11 at least in that the light emitting elements LD of the non-repair pixel PXL_N and the repair light emitting elements LD_R of the repair pixel PXL_R. Thus, detailed description of the same or similar constituent elements is omitted.

For example, the light emitting elements LD of the non-repair pixel PXL_N may be light emitting elements of a lateral type. The light emitting elements LD other than the repair light emitting element LD_R of the repair pixel PXL_R may be the light emitting elements of the lateral type. The repair light emitting element LD_R of the repair pixel PXL_R may be a light emitting element of a flip chip type.

According to an embodiment, even though the light emitting elements LD of the non-repair pixel PXL_N are light emitting elements of a lateral type, the repair light emitting elements LD_R of the repair pixel PXL_R may be transferred to be the light emitting element of the flip chip type. After the repair process is performed, an additional process for electrically connecting the first and second connection electrodes CNE1 and CNE2 and the light emitting elements LD may not be required. Thus, a process step may be simplified, and a process cost may be reduced.

According to an embodiment, the pixels PXL (for example, the non-repair pixel PXL_N and the repair pixel PXL_R) may further include an insulating pattern layer INP.

The insulating pattern layer INP may be disposed on the pixel circuit layer PCL. The insulating pattern layer INP may cover the anode electrode AE and the cathode electrode CE. The insulating pattern layer INP may include an organic material or an inorganic material. However, the disclosure is not limited thereto. The insulating pattern layer INP may form a base, and the first and second connection electrodes CNE1 and CNE2 may be disposed at a relatively high position (e.g., may be disposed on the insulating pattern layer INP).

According to an embodiment, the first and second connection electrodes CNE1 and CNE2 may be disposed on the insulating pattern layer INP. According to an embodiment, the first and second connection electrodes CNE1 and CNE2 may be electrically connected through a portion of each of the anode electrode AE and the cathode electrode CE exposed by the insulating pattern layer INP. For example, the first and second connection electrodes CNE1 and CNE2 may be electrically connected to the anode electrode AE and the cathode electrode CE, respectively.

In the non-repair pixel PXL_N, the insulating pattern layer INP may cover a side surface of the light emitting element LD. According to an embodiment, the first and second element electrodes EEL1 and EEL2 may face upward (for example, in the third direction DR3). For example, the first and second element electrodes EEL1 and EEL2 of the non-repair pixel PXL_N may be disposed on the light emitting element LD and disposed over the insulating pattern layer INP. In the non-repair pixel PXL_N, the first and second connection electrodes CNE1 and CNE2 may be disposed on the insulating pattern layer INP, and thus the first and second connection electrodes CNE1 and CNE2 may be stably electrically connected to the first and second element electrodes EEL1 and EEL2.

In the repair pixel PXL_R, a portion of the insulating pattern layer INP may be disposed on the anode electrode AE and the cathode electrode CE, and may have ends (or end portions) corresponding to the anode electrode AE and the cathode electrode CE.

In the repair pixel PXL_R, the connection metal portion COM may cover a side surface of the insulating pattern layer INP (for example, an end or an end portion of the insulating pattern layer INP).

According to an embodiment, the insulating pattern layer INP, the anode electrode AE, and the first connection electrode CNE1 may overlap each other in a plan view. The insulating pattern layer INP, the cathode electrode CE, and the second connection electrode CNE2 may overlap each other in a plan view.

For example (e.g., refer to FIG. 13), the insulating pattern layer INP, the anode electrode AE, and the first connection electrode CNE1 may have ends (or end portions) that overlap each other in a plan view. The insulating pattern layer INP, the cathode electrode CE, and the second connection electrode CNE2 may have ends (or end portions) that overlap each other in a plan view.

In other embodiments (e.g., refer to FIG. 14), the insulating pattern layer INP may be inserted into ends (or end portions) of the anode electrode AE and the first connection electrode CNE1, and may have an end (or an end portion) that does not overlap the anode electrode AE or the first connection electrode CNE1 in a plan view. The insulating pattern layer INP may form a step with respect to the anode electrode AE and the first connection electrode CNE1. The insulating pattern layer INP may be inserted into ends (or end portions) of the cathode electrode CE and the second connection electrode CNE2, and may have an end (or an end portion) that does not overlap the cathode electrode CE or the second connection electrode CNE2 in a plan view. The insulating pattern layer INP may form a step with respect to the cathode electrode CE and the second connection electrode CNE2.

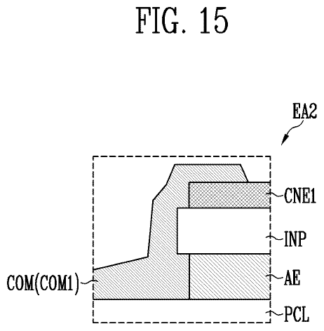

In other embodiments (e.g., refer to FIG. 15), the insulating pattern layer INP may protrude with respect to the ends (or the end portions) of the anode electrode AE and the first connection electrode CNE1, and may have the end (or the end portion) that does not overlap the anode electrode AE or the first connection electrode CNE1 in a plan view. The insulating pattern layer INP may form a step with respect to the anode electrode AE and the first connection electrode CNE1. The insulating pattern layer INP may protrude with respect to the ends (or end portions) of the cathode electrode CE and the second connection electrode CNE2, and may have the end (or the end portion) that does not overlap the cathode electrode CE or the second connection electrode CNE2 in a plan view. The insulating pattern layer INP may form a step with respect to the cathode electrode CE and the second connection electrode CNE2.

According to an embodiment, as described above, since the connection metal portion COM provided in a liquid form during the repair process covers the side surfaces of the anode electrode AE and the first connection electrode CNE1 and the side surfaces of the cathode electrode CE and the second connection electrode CNE2, an electrical connection structure (e.g., an electrical connection structure between the first connection metal portion COM1, the anode electrode AE, and the first connection electrode CNE1, an electrical connection structure between the second connection metal portion COM2, the cathode electrode CE, and the second connection electrode CNE2) may be stably formed in the repair pixel PXL_R. Even in a case where the insulating pattern layer INP is disposed (e.g., interposed) between the anode electrode AE and the first connection electrode CNE1 and between the cathode electrode CE and the second connection electrode CNE2, and the insulating pattern layer INP forms an uneven side surface with respect to the cathode electrode CE, the anode electrode AE, and the first and second connection electrodes CNE1 and CNE2, the connection metal portion COM may be provided in a liquid form, and an electrical connection structure may be stably formed between the first element electrode EEL1, the anode electrode AE, and the first connection electrode CNE1 and between the second element electrode EEL2, the cathode electrode CE, and the second connection electrode CNE2.

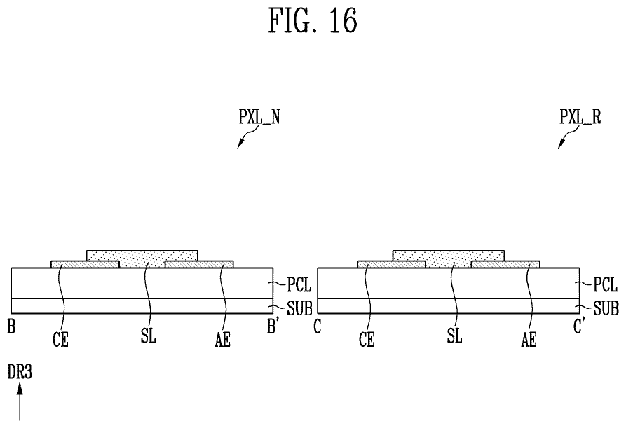

With reference to FIGS. 16 to 25, a method of manufacturing a display device DD according to an embodiment is described.

With reference to FIGS. 16 to 21, a method of manufacturing the display device DD according to an embodiment described above with reference to FIGS. 9 to 11 is described. Detailed description of the same constituent element is omitted and not repeated.

FIGS. 16 to 21 are schematic cross-sectional views for each process step illustrating a method of manufacturing a display device according to an embodiment. For convenience of description, FIGS. 16 to 21 are shown based on the cross-sectional structure described above with reference to FIG. 9.

FIGS. 16 to 21 show a cross-sectional structure for manufacturing the non-repair pixel PXL_N and a cross-sectional structure for manufacturing the repair pixel PXL_R during the manufacturing process of the display device DD according to an embodiment.

Referring to FIG. 16, the substrate SUB may be provided. The semiconductor layer, the conductive layer, and the insulating layer may be patterned on the substrate SUB to form the pixel circuit PXC (e.g., refer to FIG. 8). Thus, the pixel circuit layer PCL may be provided. The anode electrode AE and the cathode electrode CE may be patterned on the pixel circuit layer PCL, and the lower layer SL covering the anode electrode AE and the cathode electrode CE may be patterned. For example, the lower layer SL may cover a portion of the anode electrode AE and a portion of the cathode electrode CE.

According to an embodiment, the conductive layer or the insulating layer on the substrate SUB may be formed based on a process (e.g., a typical process) for manufacturing a semiconductor device. For example, the conductive layer or the insulating layer may be formed on the substrate SUB by a photolithography process. For example, the conductive layer or the insulating layer may be etched by various methods (wet etching, dry etching, and the like), and may be deposited by various methods (e.g., sputtering, chemical vapor deposition method, and the like). However, the disclosure is not limited thereto.

In this step (e.g., the forming of the conductive layer or the insulating layer), the anode electrode AE and the cathode electrode CE may be patterned and spaced apart from each other in the non-repair pixel PXL_N and the repair pixel PXL_R. For example, the anode electrode AE may include patterns disposed in the non-repair pixel PXL_N and the repair pixel PXL_R, respectively, and the cathode electrode CE may include patterns disposed in the non-repair pixel PXL_N and the repair pixel PXL_R, respectively.

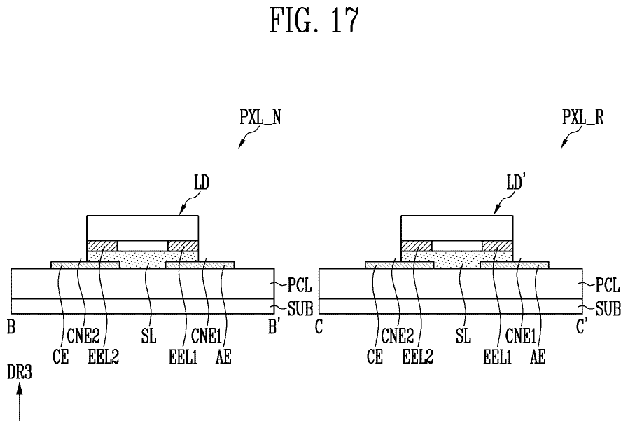

Referring to FIG. 17, the light emitting elements LD and LD′ may be disposed (for example, transferred) in the non-repair pixel PXL_N and the repair pixel PXL_R.

A method in which the light emitting elements LD and LD′ are transferred is not limited thereto. For example, in this step (e.g., the disposing of the light emitting elements LD), the light emitting elements LD and LD′ may be transferred using a laser bonding process, a thermocompression bonding process, a eutectic bonding process, or the like.

In this step (e.g., the disposing of the light emitting elements LD and LD′), the light emitting elements LD and LD′ may be transferred, and the first and second element electrodes EEL1 and EEL2 may face downward (e.g., in an opposite direction to the third direction DR3). Thus, the light emitting elements LD and LD′ may have a flip chip type structure.

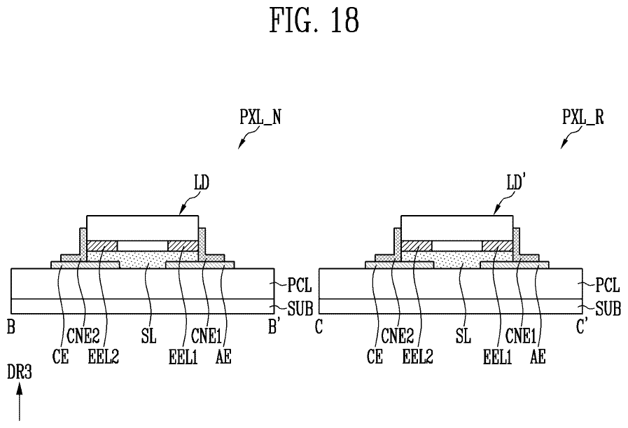

Referring to FIG. 18, the first and second connection electrodes CNE1 and CNE2 may be patterned in the non-repair pixel PXL_N and the repair pixel PXL_R. For example, patterns of the first connection electrode CNE1 may be disposed in the non-repair pixel PXL_N and the repair pixel PXL_R, respectively, and patterns of the second connection electrodes CNE2 may be disposed in the repair pixel PXL_R, respectively.

In this step (e.g., the patterning of the first and second connection electrodes CNE1 and CNE2), the first connection electrode CNE1 may be patterned to electrically connect the anode electrode AE and the first element electrode EEL1. The second connection electrode CNE2 may be patterned to electrically connect the cathode electrode CE and the second element electrode EEL2.

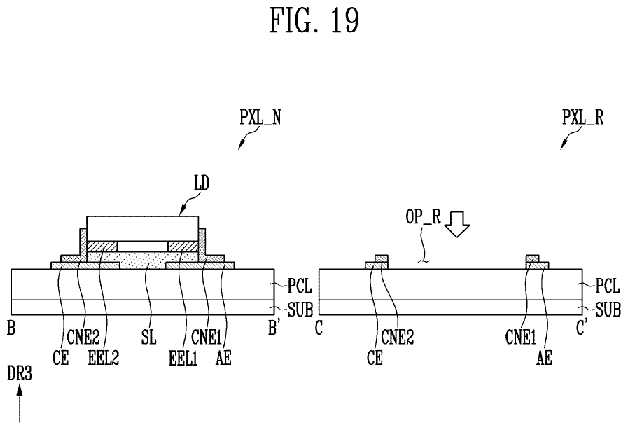

Referring to FIG. 19, the manufactured light emitting elements LD may be inspected, and a portion of the light emitting elements LD and LD′, which operates abnormally, may be determined to be an abnormal light emitting element LD′. Accordingly, the abnormal light emitting element LD′ determined to abnormally operate in the repair pixel PXL_R may be removed.

In this step (e.g., the removing of the abnormal light emitting element LD′), a laser process for removing the abnormal light emitting element LD′ in the repair pixel PXL_R may be performed. In case that the laser is irradiated, the abnormal light emitting element LD′ in the repair pixel PXL_R may be removed, and at least a portion of electrodes adjacent to the abnormal light emitting element LD′ in the repair pixel PXL_R may be removed.

In this step (e.g., the removing of the at least a portion of the electrodes adjacent to the abnormal light emitting element LD′ in the repair pixel PXL_R), at least a portion of each of the first and second connection electrodes CNE1 and CNE2, the anode electrode AE, and the cathode electrode CE may be removed, and a repair opening OPN_R may be formed in the repair pixel PXL_R.

In this step (e.g., the forming of the repair opening OPN_R), the anode electrode AE and the first connection electrode CNE1 may have substantially (or generally) corresponding ends (or end portions), and the cathode electrode CE and the second connection electrode CNE2 may have substantially (or generally) corresponding ends (or end portions).

According to an embodiment, the repair process may not be applied to the non-repair pixel PXL_N.

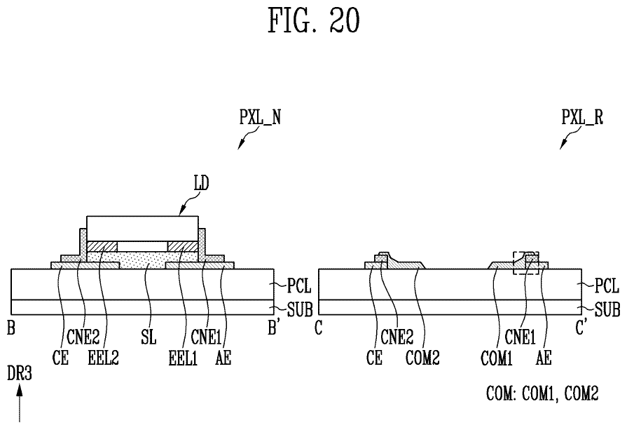

Referring to FIG. 20, the connection metal portion COM may be formed in the repair pixel PXL_R.

In this step (e.g., the forming of the connection metal portion COM in the repair pixel PXL_R), the connection metal portion COM may be provided in the repair opening OPN_R. A conductive material having a liquid form may be provided to the repair opening OPN_R (e.g., refer to FIG. 19), and at least a portion of the conductive material having the liquid form (or liquid state) may cover an upper surface of the first and second connection electrodes CNE1 and CNE2. Thus, the connection metal portion COM may be manufactured in the repair pixel PXL_R.

In this step (e.g., the forming of the connection metal portion COM in the repair opening OPN_R), since the connection metal portion COM is printed in a liquid state, the connection metal portion COM may have fluidity. Accordingly, the connection metal portion COM may thoroughly cover an outer surface of each of the first and second connection electrodes CNE1 and CNE2, the anode electrode AE, and the cathode electrode CE during the manufacturing process.

In this step (e.g., the covering by the connection metal portion COM), a liquid metal forming the connection metal portion COM may be adjacent to (for example, directly adjacent to) end portions (for example, side surfaces) of each of the first and second connection electrodes CNE1 and CNE2, the anode electrode AE, and the cathode electrode CE.

According to an embodiment, after the connection metal portion COM is provided, the connection metal portion COM may be hardened.

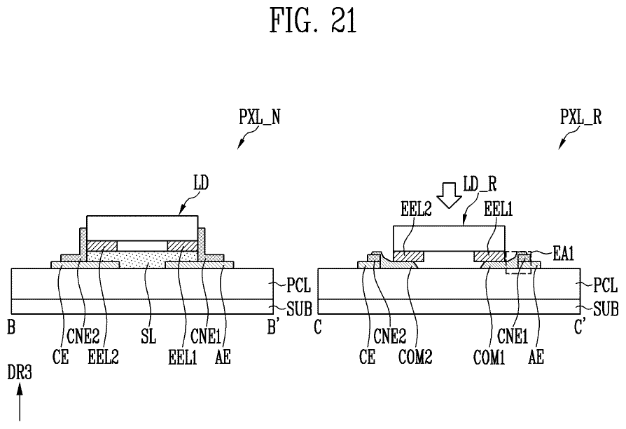

Referring to FIG. 21, the repair light emitting element LD_R may be disposed (for example, transferred) in the repair pixel PXL_R.

In this step (e.g., the disposing of the repair light emitting element LD_R), the repair light emitting element LD_R may be transferred, and the first and second element electrodes EEL1 and EEL2 of the repair light emitting element LD_R may face downward (in an opposite direction to the third direction DR3).

Accordingly, the repair process may be properly performed, and the non-repair pixel PXL_N and the repair pixel PXL_R may normally operate.

According to an embodiment, the light functional layer LFL (e.g., refer to FIG. 2) and the like may be disposed on the light emitting elements LD and LD_R (or the display element layer DPL). Thus, the display device DD according to an embodiment may be provided.

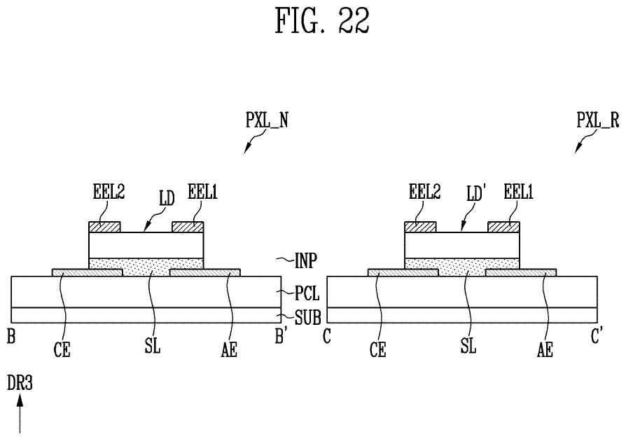

With reference to FIGS. 22 to 25, a method of manufacturing the display device DD according to an embodiment described above with reference to FIGS. 12 to 15 is described. Detailed description of the same constituent element is omitted and not repeated.

FIGS. 22 to 25 are schematic cross-sectional views for each process step illustrating a method of manufacturing a display device according to an embodiment. For convenience of description, FIGS. 22 to 25 are shown based on the cross-sectional structure described above with reference to FIG. 12.

FIGS. 22 to 25 show a cross-sectional structure for manufacturing the non-repair pixel PXL_N and a cross-sectional structure for manufacturing the repair pixel PXL_R during the manufacturing process of the display device DD according to an embodiment.

Referring to FIG. 22, the process steps described above with reference to FIG. 16 may be performed, and the light emitting elements LD and LD′ may be disposed (for example, transferred) in the non-repair pixel PXL_N and the repair pixel PXL_R.

In this step (e.g., the disposing of the light emitting elements LD and LD′), the light emitting elements LD and LD′ may be transferred, and the first and second element electrodes EEL1 and EEL2 may face upward (e.g., in the third direction DR3). Thus, the light emitting elements LD and LD′ may have a flip chip type structure.

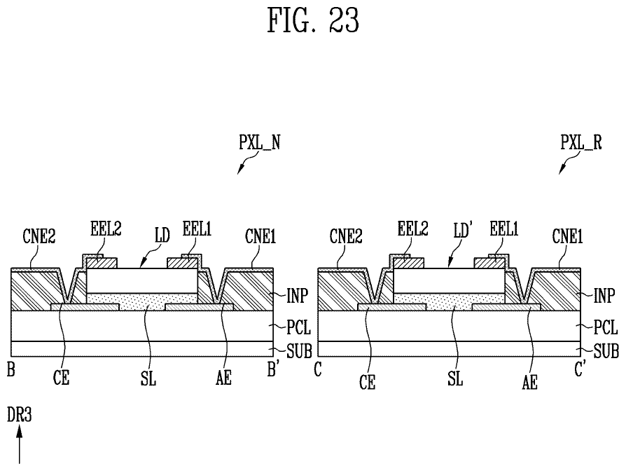

Referring to FIG. 23, the insulating pattern layer INP, the first connection electrode CNE1, and the second connection electrode CNE2 may be patterned.

In this step (e.g., the patterning of the insulating pattern layer INP, the first connection electrode CNE1, and the second connection electrode CNE2), the insulating pattern layer INP may be patterned and expose the anode electrode AE and the cathode electrode CE. Accordingly, the first connection electrode CNE1 may electrically connect the anode electrode AE and the first element electrode EEL1 of each of the light emitting elements LD and LD′, and the second connection electrode CNE2 may electrically connect the cathode electrode CE and the second element electrode EEL2 of each of the light emitting elements LD and LD′.

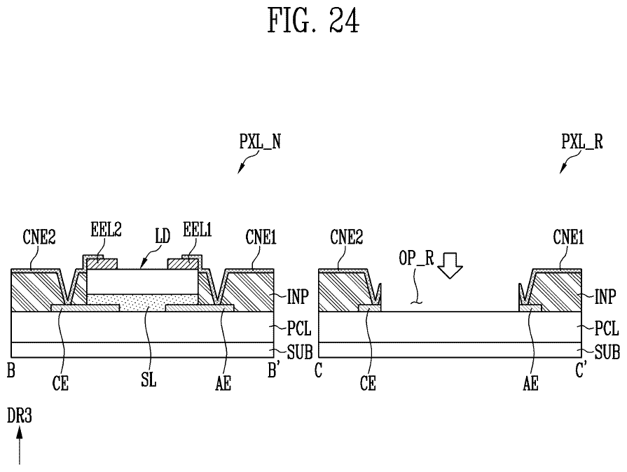

Referring to FIG. 24, the manufactured light emitting elements LD and LD′ (e.g., refer to FIG. 23) may be inspected, and a portion of the light emitting elements LD and LD′, which operate abnormally, may be determined to be an abnormal light emitting element LD′. Accordingly, the abnormal light emitting element LD′ determined to abnormally operate in the repair pixel PXL_R may be removed.

In this step (e.g., the removing of the abnormal light emitting element LD), a laser process for removing the abnormal light emitting element LD′ in the repair pixel PXL_R may be performed. In case that the laser is irradiated, the abnormal light emitting element LD′ in the repair pixel PXL_R may be removed, and at least a portion of each of the first and second connection electrodes CNE1 and CNE2, the anode electrode AE, the cathode electrode CE, and the insulating pattern layer INP adjacent to the abnormal light emitting element LD′ in the repair pixel PXL_R may be removed. Thus, the repair opening OP_R may be formed in the repair pixel PXL_R.

In this step (e.g., the removing of the at least a portion of the electrodes adjacent to the abnormal light emitting element LD′ in the repair pixel PLX_R), the anode electrode AE, the insulating pattern layer INP, and the first connection electrode CNE1 may have substantially (or generally) corresponding ends (or end portions), and the cathode electrode CE, the insulating pattern layer INP, and the second connection electrode CNE2 may have substantially (or generally) corresponding ends (or end portions).

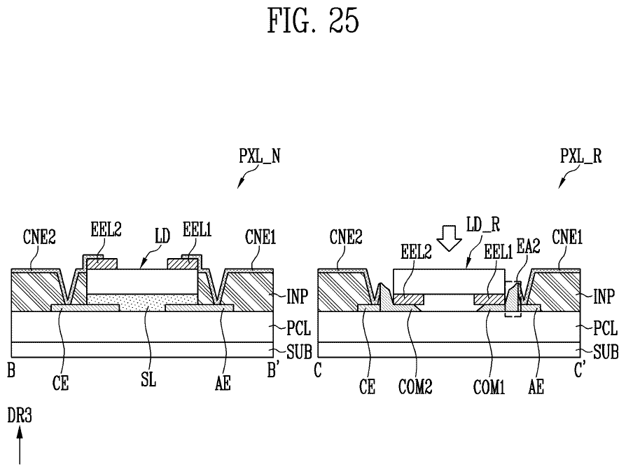

Referring to FIG. 25, the connection metal portion COM may be formed in the repair pixel PXL_R, and the repair light emitting element LD_R may be disposed (for example, transferred) in the repair pixel PXL_R and electrically connected to the connection metal portion COM.

In this step (e.g., the disposing of the connection metal portion COM), the connection metal portion COM may be provided in the repair opening OPN_R. A conductive material having a liquid form may be provided to the repair opening OPN_R, and at least a portion of the conductive material having the liquid form may cover an upper surface of the first and second connection electrodes CNE1 and CNE2. Thus, the connection metal portion COM may be manufactured.

In this step (e.g., the manufacturing of the connection metal portion COM), the repair light emitting element LD_R may be transferred, and the first and second element electrodes EEL1 and EEL2 of the repair light emitting element LD_R may face downward (e.g., in an opposite direction to the third direction DR3).

According to an embodiment, the light functional layer LFL (e.g., refer to FIG. 2) and the like may be disposed on the light emitting elements LD and LD_R (or the display element layer DPL). Thus, the display device DD according to an embodiment may be provided.

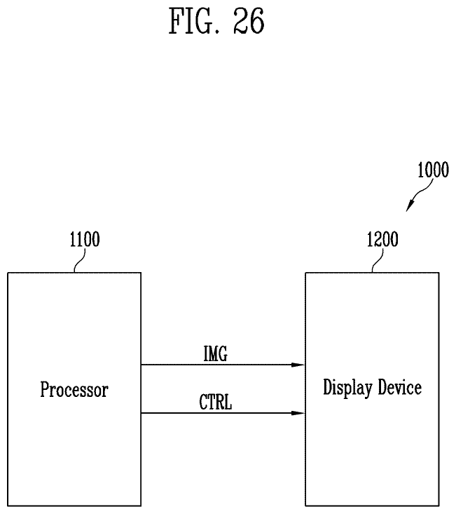

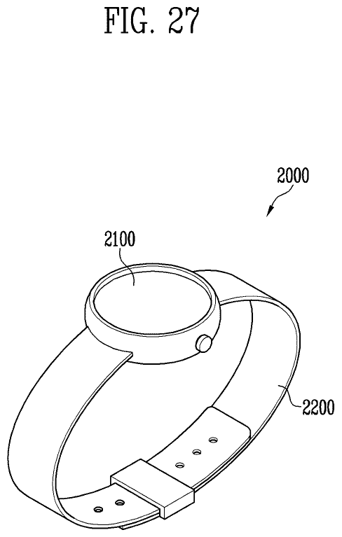

FIG. 26 is a block diagram illustrating an embodiment of an electronic device.

Referring to FIG. 26, the electronic device 1000 may include a processor 1100 and a display device 1200. The electronic device 1000 may implement a display system.

The processor 1100 may perform various tasks, calculations, operations, or the like. In other embodiments, the processor 1100 may include an application processor, a graphics processor, a microprocessor, a central processing unit (CPU), and the like. The processor 1100 may be electrically connected to other components of the electronic device 1000 through a bus system and control the components.

The processor 1100 may transmit image data IMG and a control signal CTRL to the display device 1200. The display device 1200 may display an image based on the image data IMG and the control signal CTRL. The display device 1200 may be configured similarly to the display device DD described above.

The electronic device 1000 may include a computing system providing an image display, such as a smart watch, a mobile phone, a smart phone, a portable computer, a tablet personal computer (PC), a watch phone, an automotive display, smart glasses, a portable multimedia player (PMP), a navigation device, an ultra mobile personal computer (UMPC), or the like. The electronic device 1000 may include at least one of a head mounted display (HMD) device, a virtual reality (VR) device, a mixed reality (MR) device, and an augmented reality (AR) device. However, the disclosure is not limited thereto.

According to an embodiment, the electronic device 1000 may further include a memory device, a storage device, an input/output (I/O) device, and a power supply.

The memory device may store data needed to perform the operation of the electronic device 1000. The memory device may function as a working memory and/or a buffer memory for the processor. For example, the memory device may include one or more volatile memory devices such as a dynamic random access memory (DRAM) device, a static random access memory (SRAM) device, and a mobile DRAM device.

The storage device may store data in response to control signals or data from the processor. The storage device may include one or more non-volatile storages to retain the data in case that the electronic device 1000 is powered off. In some embodiments, the storage device may include a solid state drive (SSD), a hard disk drive (HDD), a CD-ROM, or the like.

The I/O device may include input devices such as a keyboard, a keypad, a touchpad, a touch screen, and a mouse, and output devices such as a speaker and a printer. In an embodiment, the display device 1210, 1220 may be included in the I/O device.

The power supply may supply power needed to perform the operation of the electronic device 1000. For example, the power supply may be a power management integrated circuit (PMIC). In an embodiment, the power supply may supply power to the display device 1210, 1220.

FIGS. 27 to 30 are perspective views illustrating application examples of the electronic device of FIG. 26.

Referring to FIG. 27, the electronic device 1000 of FIG. 26 may be applied to a smart watch 2000 including a display part 2100 and a strap part 2200.

The smart watch 2000 may be a wearable electronic device. For example, the strap part 2200 of the smart watch 2000 may be mounted on a user's wrist. The electronic device 1000 (e.g., refer to FIG. 26) and/or the display device 1200 (e.g., refer to FIG. 26) may be applied to the display part 2100, and image data including time information may be provided to a user.

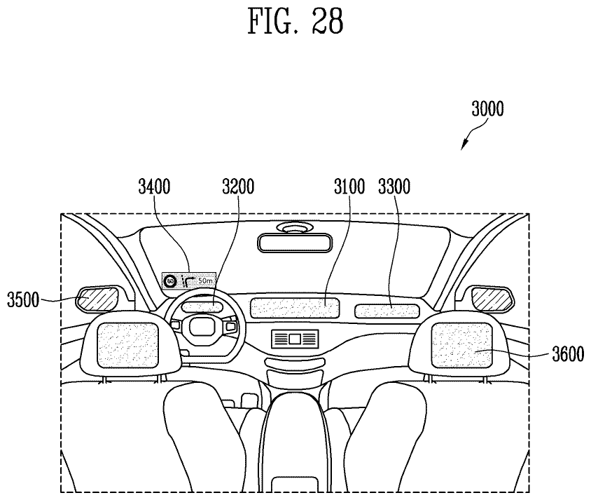

Referring to FIG. 28, the electronic device 1000 of FIG. 26 may be applied to an automotive electronic device 3000. The automotive electronic device 3000 may include a computing system provided inside and/or outside a vehicle to provide image data.

For example, the electronic device 1000 (e.g., refer to FIG. 26) and/or the display device 1200 (e.g., refer to FIG. 26) may be applied to at least one of an infotainment panel 3100, a cluster 3200, a co-driver display 3300, a head-up display 3400, a side mirror display 3500, and a rear seat displays 3600 provided in a vehicle.

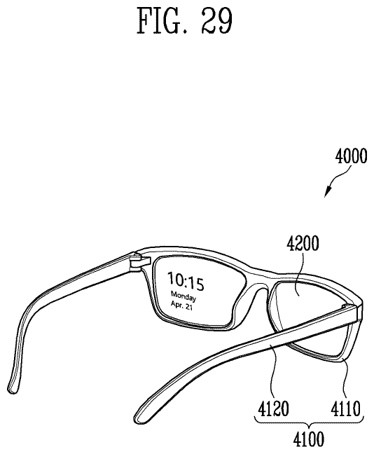

Referring to FIG. 29, the electronic device 1000 of FIG. 26 may be applied to smart glasses 4000. The smart glasses 4000 may be a wearable electronic device that may be worn on a user's head. For example, the smart glasses 4000 may be a wearable device for augmented reality.

The smart glasses 4000 may include a frame 4100 and a lens part 4200. The frame 4100 may include a housing 4110 that supports the lens part 4200 and a leg part 4120 for the user to wear. The leg part 4120 may be extended to (or be connected to) the housing 4110 through a hinge and may be folded or unfolded relative to the housing 4110.

A battery, a touch pad, a microphone, a camera, and the like may be built in the frame 4100. A projector that outputs light, a processor that controls a light signal, and the like may be built in the frame 4100.

The lens part 4200 may include an optical member that transmits or reflects light. For example, the lens part 4200 may include glass, transparent synthetic resin, or the like.

In order for user's eyes to recognize visual information, the lens part 4200 may reflect an image by the light signal transmitted from the projector of the frame 4100 by a rear surface (for example, a surface of a direction facing the user's eyes) of the lens part 4200. For example, the image may be generated by the light signal, and the projector of the frame 4100 may transmit and display the image on the rear surface (e.g., the surface of the direction facing the user's eyes) of the lens part 4200. For example, the user may recognize visual information such as time and date displayed on the lens part 4200 (e.g., the rear surface of the lens part 4200). The projector and/or the lens part 4200 may be a type of a display device. The display device 1200 (e.g., refer to FIG. 26) may be applied to the projector and/or the lens part 4200.

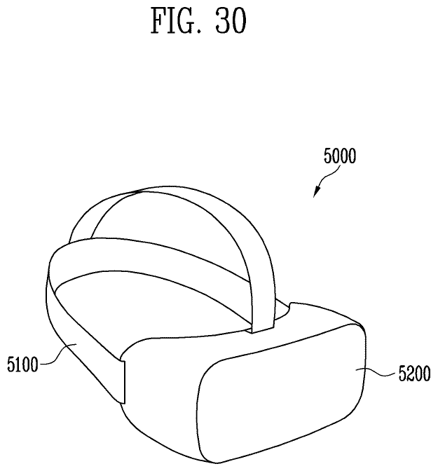

Referring to FIG. 30, the electronic device 1000 of FIG. 26 may be applied to a head mounted display device 5000.

The head mounted display device 5000 may be a wearable electronic device that may be worn on a user's head. For example, the head mounted display device 5000 may be a wearable device for virtual reality or mixed reality.

The head mounted display device 5000 may include a head mount band 5100 and a display device receiving case 5200. The head mount band 5100 may be extended to (or be connected to) the display device receiving case 5200. The head mount band 5100 may include a horizontal band and/or a vertical band for fixing the head mounted display device 5000 to a user's head. The horizontal band may be adjacent to (e.g., surround) a side portion of the user's head, and the vertical band may be adjacent to (e.g., surround) an upper portion of the user's head. However, the disclosure is not limited thereto. For example, the head mount band 5100 may be implemented in a form of a glasses frame, a helmet, or the like.

The display device receiving case 5200 may receive the electronic device 1000 (e.g., refer to FIG. 26) and/or the display device 1200 (e.g., refer to FIG. 26).

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first pixel and a second pixel disposed on a substrate and having different structures from each other, each of the first and second pixels comprising:
a light emitting element including:
a first element electrode; and
a second element electrode;
an anode electrode disposed on the substrate;
a cathode electrode disposed on the substrate;
a first connection electrode electrically connecting the anode electrode and the light emitting element; and
a second connection electrode electrically connecting the cathode electrode and the light emitting element,
wherein the second pixel further includes:
a first connection metal portion that electrically connects the anode electrode and the first element electrode; and
a second connection metal portion that electrically connects the cathode electrode and the second element electrode.

2. The display device of claim 1, wherein the first and second connection metal portions are not included in the first pixel.

3. The display device of claim 1, wherein the first connection metal portion and the second connection metal portion are spaced apart from each other in a direction in which the anode electrode and the cathode electrode are spaced apart from each other.

4. The display device of claim 3, wherein
each of the first and second pixels includes:
a first sub-pixel including a first anode electrode of the anode electrode;
a second sub-pixel including a second anode electrode of the anode electrode; and
a third sub-pixel including a third anode electrode of the anode electrode,
the cathode electrode is a common electrode for the first sub-pixel, the second sub-pixel, and the third sub-pixel,
the light emitting element of each of the first and second pixels includes:
a first light emitting element electrically connected to the first anode electrode;
a second light emitting element electrically connected to the second anode electrode; and
a third light emitting element electrically connected to the third anode electrode,
at least one of the first light emitting element, the second light emitting element, and the third light emitting element of the second pixel is a repair light emitting element, and
the repair light emitting element is electrically connected to the first and second connection metal portions.

5. The display device of claim 4, wherein at least a portion of the first and second connection metal portions is disposed around the repair light emitting element in a plan view.

6. The display device of claim 1, wherein at least a portion of each of the first connection metal portion and the second connection metal portion is disposed between the anode electrode and the cathode electrode.

7. The display device of claim 1, wherein at least one of the first and second connection metal portions covers a side surface of each of the anode electrode and the cathode electrode.

8. The display device of claim 7, wherein the anode electrode and the first connection electrode have end portions that do not overlap each other in a plan view.

9. The display device of claim 1, wherein each of the first and second connection metal portions includes at least one of silver (Ag), copper (Cu), and gold (Au).

10. The display device of claim 1, wherein
the light emitting element includes a repair light emitting element electrically connected to the first and second connection metal portions in the second pixel,
in the first pixel, the first element electrode and the second element electrode of the light emitting element face the substrate, and
in the second pixel, the first element electrode and the second element electrode of the repair light emitting element face the substrate.

11. The display device of claim 1, wherein
the light emitting element includes a repair light emitting element electrically connected to the first and second connection metal portions in the second pixel,
in the first pixel, the first element electrode and the second element electrode of the light emitting element face an upper portion of the display device, and
in the second pixel, the first element electrode and the second element electrode of the repair light emitting element face the substrate.

12. The display device of claim 11, further comprising:
an insulating pattern layer covering a portion of each of the anode electrode and the cathode electrode and forming a base on which the first connection electrode and the second connection electrode are disposed, and
wherein in the second pixel, a side surface of the insulating pattern layer is adjacent to at least one of the first and second connection metal portions.

13. The display device of claim 12, wherein in the second pixel, the at least one of the first and second connection metal portions covers a side surface of each of the insulating pattern layer, the anode electrode, and the first connection electrode.

14. The display device of claim 13, wherein in the second pixel, the insulating pattern layer has an end portion that does not overlap end portions of the anode electrode and the first connection electrode in a plan view.

15. A method of manufacturing a display device including a non-repair pixel and a repair pixel, the method comprising:
patterning an anode electrode and a cathode electrode in each of the non-repair pixel and the repair pixel on a substrate;
disposing a light emitting element including a first element electrode and a second element electrode on the anode electrode and the cathode electrode in each of the non-repair pixel and the repair pixel;
patterning a first connection electrode electrically connecting the anode electrode and the first element electrode and a second connection electrode electrically connecting the cathode electrode and the second element electrode in each of the non-repair pixel and the repair pixel;
removing the light emitting element in the repair pixel;
forming a connection metal portion in the repair pixel by providing a conductive material having a liquid crystal state; and
disposing a repair light emitting element on the connection metal portion.

16. The method of claim 15, wherein
the forming of the connection metal portion comprises printing a liquid metal, and
the removing of the light emitting element comprises removing the light emitting element using a laser.

17. The method of claim 16, further comprising:
forming a repair opening by removing at least a portion of each of the anode electrode, the cathode electrode, the first connection electrode, and the second connection electrode in the repair pixel.

18. The method of claim 17, wherein the forming of the connection metal portion comprises:
providing the liquid metal to the repair opening; and
disposing the liquid metal on end portions of each of the anode electrode, the cathode electrode, the first connection electrode, and the second connection electrode adjacent to the repair opening.

19. The method of claim 15, wherein the repair light emitting element in the repair pixel and the light emitting element in the non-repair pixel are light emitting elements of a flip chip type.

20. The method of claim 15, wherein
the repair light emitting element in the repair pixel is a light emitting element of a flip chip type, and
the light emitting element in the non-repair pixel is a light emitting element of a lateral type.

21. An electronic device, comprising:
a processor that provides input image data;
a display device that displays an image based on the input image data, the display device including sub-pixel areas; and
a power supply that supplies power to the display device,
wherein the display device comprises:
a first pixel and a second pixel disposed on a substrate and having different structures from each other, each of the first and second pixels comprising:
a light emitting element including:
a first element electrode; and
a second element electrode;
an anode electrode disposed on the substrate;
a cathode electrode disposed on the substrate;
a first connection electrode electrically connecting the anode electrode and the light emitting element; and
a second connection electrode electrically connecting the cathode electrode and the light emitting element,
wherein the second pixel further includes:
a first connection metal portion that electrically connects the anode electrode and the first element electrode; and
a second connection metal portion that electrically connects the cathode electrode and the second element electrode.
